(19) United States
(12) Patent Application Publication
(10) Pub. No.: US 2008/0265339 A1
(43) Pub. Date: Oct. 30, 2008

(54) SEMICONDUCTOR INTEGRATED CIRCUIT

(76) Inventor: Shigeyuki KOMATSU, Kyoto (JP)

Correspondence Address: MCDERMOTT WILL & EMERY LLP, 600 13TH STREET, NW, WASHINGTON, DC, 20005-3096, US

(21) Appl. No.: 12/044,400

(22) Filed: Mar. 7, 2008

(30) Foreign Application Priority Data
Mar. 9, 2007 (JP) 2007-060543

(51) Int. Cl. H01L 27/088; H03K 17/687

(52) U.S. Cl. 257/401; 327/427; 257/E27.06

(57) ABSTRACT

The semiconductor integrated circuit includes: a first electrode; a transistor, having a second electrode, formed on a semiconductor substrate; and third and fourth electrodes formed in a same metal layer. The first electrode is connected with a diffusion region constituting the transistor. The second electrode constitutes the gate of the transistor. The third and fourth electrodes are respectively in a comb shape and formed to at least partly overlie the transistor. None of the first to fourth electrodes is connected with any of the other electrodes.

### CROSS-REFERENCE TO RELATED APPLICATIONS

This application claims priority under 35 U.S.C. §119 on Patent Application No. 2007-60543 filed in Japan on Mar. 9, 2007, the entire contents of which are hereby incorporated by reference.

### BACKGROUND OF THE INVENTION

The present invention relates to a semiconductor integrated circuit, and more particularly to a semiconductor integrated circuit having a capacitance element.

With recent remarkable progress in semiconductor processes, semiconductor integrated circuits have been reduced in chip area year by year. Along with reduction in interconnect pitch and transistor pitch on layout, high density has been attained in digital circuits. In analog circuits, however, it is difficult to attain area reduction. This is because analog circuits need to have capacitances, resistances and transistors of some sizes to satisfy the characteristics and precision required. For this reason, the ratio of the area of analog circuits to the entire chip area increases, and this prevents attainment of cost reduction.

In view of the above, to reduce the layout area of the capacitance in an analog circuit, a capacitance element using inter-wire capacitance has come into use along with the recent reduction in interconnect pitch. For example, a capacitance element using two comb electrodes is known (see Japanese Laid-Open Patent Publication No. 61-263251 (FIG. 1), for example).

With the application of such a capacitance element to an analog circuit, the circuit area may be reduced. However, since no substantial reduction is attainable, the difficulty in reducing the area of an analog circuit still remains.

To obtain a capacitance as large as tens to hundreds of pF required in low-pass filters and operational amplifiers, a capacitance element using a gate oxide film of a metal oxide semiconductor (MOS) transistor is generally used. The area of such a capacitance element is however too large to be negligible in a recent fine circuit.

### SUMMARY OF THE INVENTION

An object of the present invention is increasing the capacitance per unit area in a semiconductor integrated circuit.

The semiconductor integrated circuit of the present invention is provided with a transistor formed on a semiconductor substrate and two electrodes in a comb shape.

More specifically, the semiconductor integrated device of the present invention includes: a first electrode; a transistor, having a second electrode, formed on a semiconductor substrate; and third and fourth electrodes formed in a same metal layer. The first electrode is connected with a diffusion region constituting the transistor, the second electrode constitutes a gate of the transistor, and the third and fourth electrodes are respectively in a comb shape and formed to at least partly overlie the transistor. None of the first to fourth electrodes is connected with any of the other electrodes.

With the above configuration, both the capacitance generated in the transistor and the capacitance generated between the third and fourth electrodes formed to at least partly overlie the transistor can be used. Hence, the capacitance per unit area can be increased.

Alternatively, the semiconductor integrated device of the present invention includes: a first electrode; a transistor, having a second electrode, formed on a semiconductor substrate; and third and fourth electrodes formed in a same metal layer. The first electrode is connected with a diffusion region constituting the transistor, the second electrode constitutes a gate of the transistor, and the third and fourth electrodes are respectively in a comb shape and formed to at least partly overlie the transistor. The first electrode and the third electrode are connected with each other.

With the above configuration, in which the third and fourth electrodes are respectively formed to at least partly overlie the transistor, the capacitance per unit area can be increased in the semiconductor integrated circuit. Also, since the first and third electrodes are connected, capacitances can be formed between the first and second electrodes and between the first and fourth electrodes.

Alternatively, the semiconductor integrated device of the present invention includes: a first electrode; a transistor, having a second electrode, formed on a semiconductor substrate; and third and fourth electrodes formed in a same metal layer. The first electrode is connected with a diffusion region constituting the transistor, the second electrode constitutes a gate of the transistor, and the third and fourth electrodes are respectively in a comb shape and formed to at least partly overlie the transistor. The second electrode and the fourth electrode are connected with each other.

With the above configuration, in which the third and fourth electrodes are respectively formed to at least partly overlie the transistor, the capacitance per unit area can be increased in the semiconductor integrated circuit. Also, since the second and fourth electrodes are connected, capacitances can be formed between the first and second electrodes and between the second and third electrodes.

Alternatively, the semiconductor integrated circuit of the present invention includes: a capacitance circuit connected to first to third nodes; a switch circuit connected between the first node and the third node; and a switch control circuit for controlling the switch circuit so as to be ON when the voltage between the first and second nodes is low. The capacitance circuit includes: a transistor having a source and a drain connected to the first node and a gate connected to the second node; and two comb-shaped electrodes formed in a same metal layer and respectively connected to the second and third nodes.

With the above configuration, in which the switch circuit is provided, the characteristic of the capacitance between the first and second nodes can be controlled.

According to the present invention, the area of the semiconductor integrated circuit having a capacitance element can be greatly reduced. Also, since the inter-wire capacitance and the capacitance generated in a transistor can be combined, the characteristic as the capacitance element can be easily tailored to a characteristic required.

### BRIEF DESCRIPTION OF THE DRAWINGS

FIG. 1 is a layout diagram of a semiconductor integrated circuit of Embodiment 1.

FIG. 2 is a cross-sectional view of the semiconductor integrated circuit of FIG. 1 taken along line a-a′.

FIG. 3 is a circuit diagram showing a circuit equivalent to the semiconductor integrated circuit of FIG. 1.

FIG. 4 is a layout diagram of a semiconductor integrated circuit of the first alteration to Embodiment 1.

FIG. 5 is a cross-sectional view of the semiconductor integrated circuit of FIG. 4 taken along line a-a′.

FIG. 6 is a layout diagram of a semiconductor integrated circuit of the second alteration to Embodiment 1.

FIG. 7 is a cross-sectional view of the semiconductor integrated circuit of FIG. 6 taken along line a-a′.

FIG. 8 is a circuit diagram showing a circuit equivalent to the semiconductor integrated circuit of FIG. 6.

FIG. 9 is a layout diagram of a semiconductor integrated circuit of the third alteration to Embodiment 1.

FIG. 10 is a cross-sectional view of the semiconductor integrated circuit of FIG. 9 taken along line a-a′.

FIG. 11 is a circuit diagram showing a circuit equivalent to the semiconductor integrated circuit of FIG. 9.

FIG. 12 is a layout diagram of a semiconductor integrated circuit of the fourth alteration to Embodiment 1.

FIG. 13 is a cross-sectional view of the semiconductor integrated circuit of FIG. 12 taken along line a-a′.

FIG. 14 is a circuit diagram showing a circuit equivalent to the semiconductor integrated circuit of FIG. 12.

FIG. 15 is a layout diagram of a semiconductor integrated circuit of the fifth alteration to Embodiment 1.

FIG. 16 is a cross-sectional view of the semiconductor integrated circuit of FIG. 15 taken along line a-a′.

FIG. 17 is a layout diagram of an alteration to the semiconductor integrated circuit of FIG. 15.

FIG. 18 is a cross-sectional view of the semiconductor integrated circuit of FIG. 17 taken along line a-a′.

FIG. 19 is a layout diagram of a semiconductor integrated circuit of the sixth alteration to Embodiment 1.

FIG. 20 is a circuit diagram of a semiconductor integrated circuit of Embodiment 2.

FIG. 21 is a graph showing the C-V characteristic of a MOS transistor in FIG. 20.

FIG. 22 is a graph showing a capacitance CL between node B and node A by an inter-wire capacitance in FIG. 20.

FIG. 23 is a graph showing a capacitance CM+CL between node B and node A in the semiconductor integrated circuit of FIG. 20.

FIG. 24 is a circuit diagram showing an example of configuration of a semiconductor integrated circuit having a larger capacitance.

FIG. 25 is a circuit diagram showing an alteration to the semiconductor integrated circuit of FIG. 20.

FIG. 26 is a graph showing a capacitance CL between node B and node A by an inter-wire capacitance obtained when a control signal CCN is at a low potential.

FIG. 27 is a graph showing a capacitance CM+CL between node B and node A obtained when the control signal CCN is at a low potential.

### DESCRIPTION OF THE PREFERRED EMBODIMENTS

Hereinafter, preferred embodiments of the present invention will be described with reference to the accompanying drawings.

### Embodiment 1

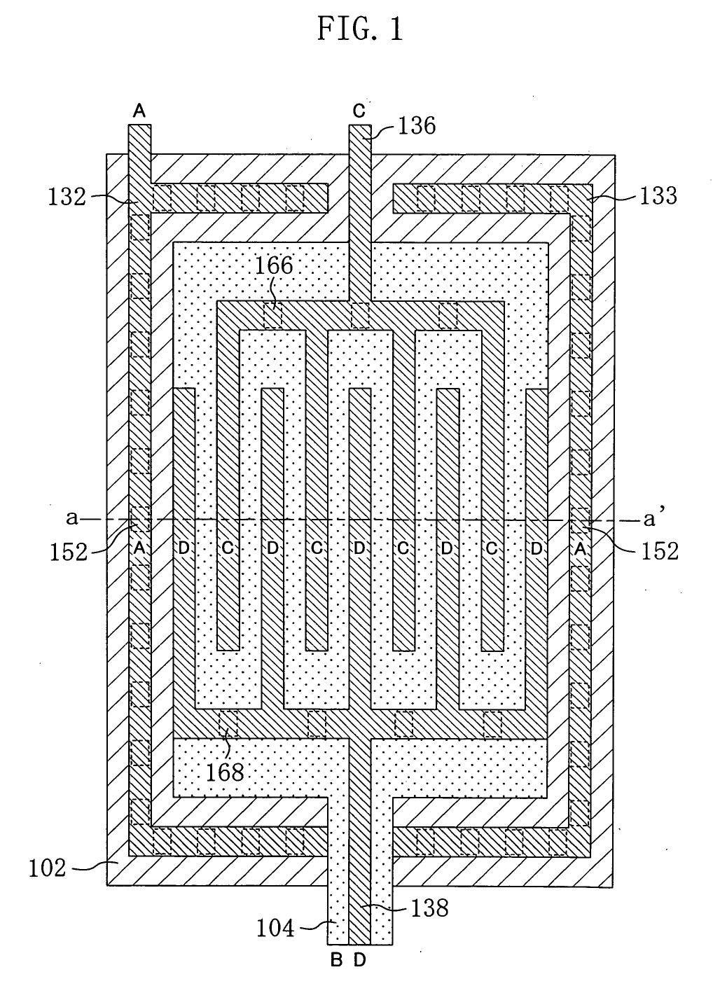

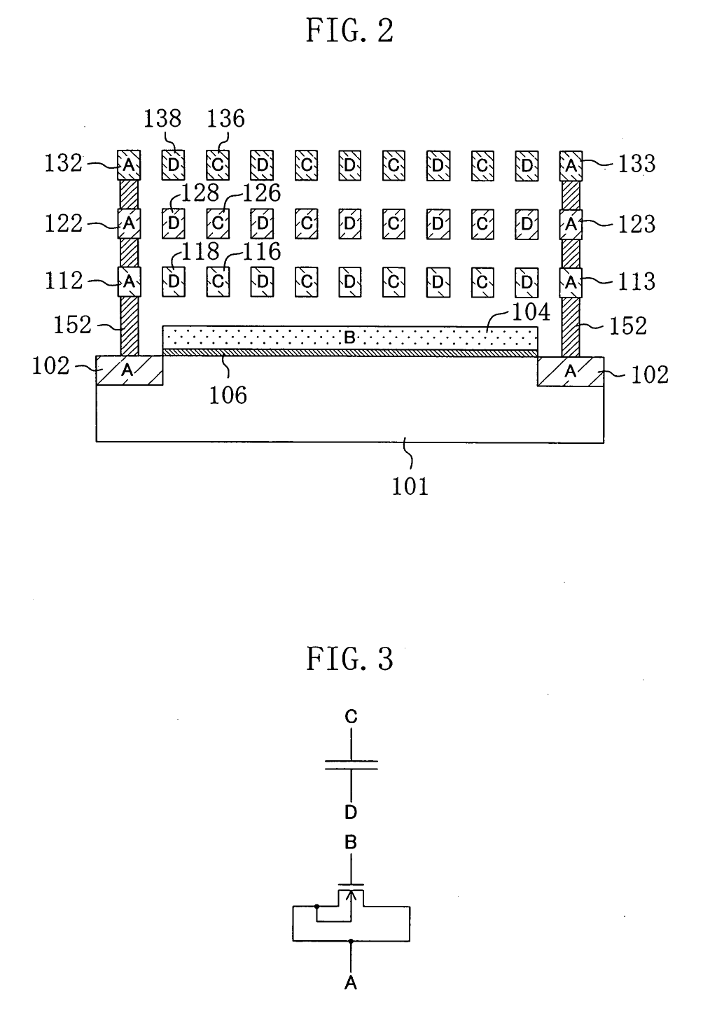

FIG. 1 is a layout diagram of a semiconductor integrated circuit of Embodiment 1. FIG. 2 is a cross-sectional view of the semiconductor integrated circuit of FIG. 1 taken along line a-a′. FIG. 3 is a circuit diagram showing a circuit equivalent to the semiconductor integrated circuit of FIG. 1.

The semiconductor integrated circuit of FIG. 1 includes a p-type semiconductor substrate 101, an n-type diffusion region 102, a gate oxide film 106, interconnects 112, 113, 122, 123, 132 and 133 as the first electrode, a polysilicon gate 104 as the second electrode, comb electrodes 116, 126 and 136 as the third electrode, and comb electrodes 118, 128 and 138 as the fourth electrode.

The diffusion region 102 is formed in the semiconductor substrate 101, and the gate oxide film 106 is formed on a portion of the semiconductor substrate 101 surrounded by the diffusion region 102. The polysilicon gate 104 is formed on the gate oxide film 106. Although not shown, the semiconductor substrate 101 and the diffusion region 102 are electrically connected with each other to have roughly the same potential. The semiconductor substrate 101, the diffusion region 102, the polysilicon gate 104 and the gate oxide film 106 constitute a MOS transistor as shown in FIG. 3, functioning as a capacitance between node A and node B (called a MOS capacitance).

It is herein assumed that the diffusion region 102 is not partitioned even at a position underlying the comb electrode 136 and the configuration having such a diffusion region 102 is still regarded as a MOS transistor. The left half of the diffusion region 102 is regarded as the source of this MOS transistor and the right half thereof as the drain of the MOS transistor.

Above the diffusion region 102, formed are the interconnects 112 and 113 in a first metal layer, the interconnects 122 and 123 in a second metal layer, and the interconnects 132 and 133 in a third metal layer. The interconnects 112, 122 and 132 are all in roughly the same shape like that shown in FIG. 1, while the interconnects 113, 123 and 133 are all in roughly the same shape like that shown in FIG. 1.

Insulating films respectively exist between the diffusion region 102/polysilicon gate 104 and the first metal layer, between the first metal layer and the second metal layer, and between the second metal layer and the third metal layer. The interconnects 112, 122 and 132 and the diffusion region 102 are connected with one another via a plurality of contact vias 152. Likewise, the interconnects 113, 123 and 133 and the diffusion region 102 are connected with one another via a plurality of contact vias 152.

The comb electrodes 116 and 118 in the first metal layer, the comb electrodes 126 and 128 in the second metal layer, and the comb electrodes 136 and 138 in the third metal layer are formed to overlie the polysilicon gate 104. The comb electrodes 116, 126 and 136 are all in roughly the same comb shape like that shown in FIG. 1, and are connected mutually via vias 166 (node C). Likewise, the comb electrodes 118, 128 and 138 are all in roughly the same comb shape like that shown in FIG. 1, and are connected mutually via vias 168 (node D).

Referring to FIG. 1, the teeth of the comb electrode 136 and the teeth of the comb electrode 138 are interdigitated to run alternately and roughly in parallel. Inter-wire capacitance is therefore generated between the comb electrodes 136 and 138. Likewise, the teeth of the comb electrode 116 and the teeth of the comb electrode 118 are interdigitated to run alternately and roughly in parallel, and the teeth of the comb electrode 126 and the teeth of the comb electrode 128 are interdigitated to run alternately and roughly in parallel.

In other words, the above comb electrodes constitute a capacitance element (inter-wire capacitance) between node C and node D as shown in FIG. 3. The magnitude of the capacitance of this element is the sum of the inter-wire capacitance between the comb electrodes 116 and 118, the inter-wire capacitance between the comb electrodes 126 and 128, and the inter-wire capacitance between the comb electrodes 136 and 138.

To increase the inter-wire capacitance, the spacing between the teeth of the comb electrode 116 and the teeth of the comb electrode 118 may be the smallest possible pitch, for example. This also applies to the spacing between the teeth of the comb electrode 126 and the teeth of the comb electrode 128 and the spacing between the teeth of the comb electrode 136 and the teeth of the comb electrode 138. In the first metal layer, the teeth of the comb electrodes 116 and 118 are roughly parallel with the interconnects 112 and 113. This also applies to the second and third metal layers.

As described above, in the semiconductor integrated circuit shown in FIGS. 1 and 2, in which the MOS capacitance is formed under the inter-wire capacitance, the capacitance value can be made larger by the value of the MOS capacitance without changing the circuit area, compared with the case of using only the inter-wire capacitance. Also, having a pair of electrodes (nodes A and B) constituting the MOS capacitance and a pair of electrodes (nodes C and D) constituting the inter-wire capacitance, a circuit can be configured by combining the four nodes freely. This enhances the convenience of design.

When the MOS transistor is of a type other than a depletion type, the capacitance value of the MOS capacitance varies with the potential difference between the source and gate of the MOS transistor. In other words, with the capacitance value being unfixed, the uses of the MOS capacitance are limited. On the contrary, as for the inter-wire capacitance, while the capacitance value is fixed irrespective of the voltage between interconnects, a capacitance value per unit area as large as that of the MOS capacitance is not obtainable. Hence, considering the cost, the uses of the inter-wire capacitance are also limited.

However, in an analog circuit using a capacitance element, the following use can be made, for example. That is, the MOS capacitance may be used when a large capacitance value is necessary but a change in capacitance value is acceptable, and the inter-wire capacitance may be used when a fixed capacitance value is necessary. In other words, in this embodiment, a capacitance element having a characteristic required by the circuit can be used depending on the purpose, and also the circuit area can be reduced. With the reduction in circuit area, degradation in analog characteristics that may occur due to a lengthened route of wiring can be prevented.

In the second metal layer, the interconnects 122 and 123 may be connected with each other via an interconnect. In this case, the comb electrode 126 may be given a shape not running between the interconnects 122 and 123. Likewise, the interconnects 132 and 133 may be connected with each other via an interconnect in the third metal layer. Otherwise, the interconnect 112, 122 or 132 may be connected with the interconnect 113, 123 or 133 at a position outside the area of FIG. 1.

Although the use of the NMOS transistor was exemplified in the above description, a PMOS transistor may also be used in the same manner. This also applies to cases to follow.

Any transistor having an insulating film between the gate electrode and the semiconductor substrate may be used in place of the MOS transistor.

In the above description, the interconnects in three metal layers were used for the inter-wire capacitance. Alternatively, interconnects in two or less or four or more metal layers may be used for the inter-wire capacitance. If a semiconductor integrated circuit has a plurality of metal layers, interconnects in any of such metal layers may be used for the inter-wire capacitance.

### First Alteration

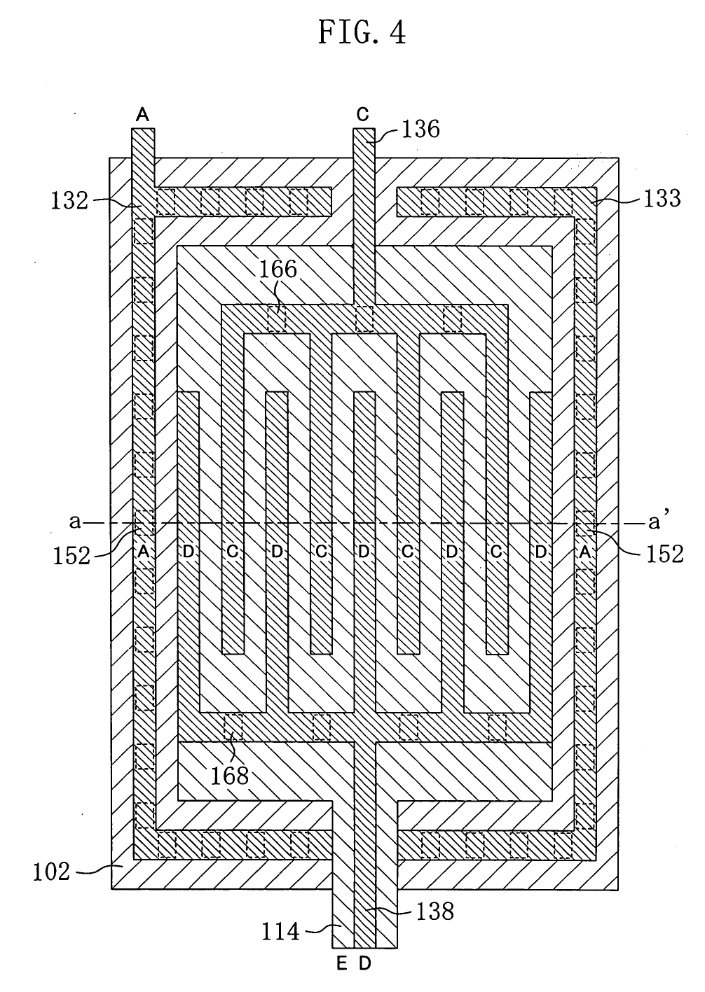

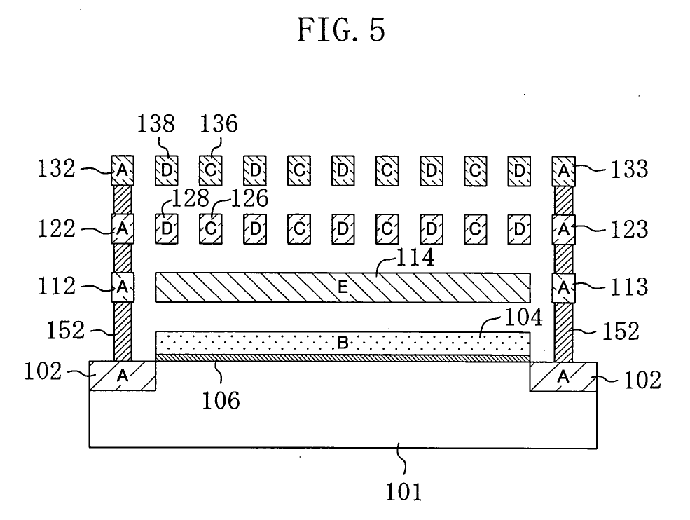

FIG. 4 is a layout diagram of a semiconductor integrated circuit of the first alteration to Embodiment 1. FIG. 5 is a cross-sectional view of the semiconductor integrated circuit of FIG. 4 taken along line a-a′. The semiconductor integrated circuit of FIG. 4 is different from the semiconductor integrated circuit of FIG. 1 in that a shield layer 114 having roughly the same shape as the polysilicon gate 104 is formed in the first metal layer in place of the comb electrodes 116 and 118. The other configuration of the semiconductor integrated circuit of FIG. 4 is substantially the same as that of the semiconductor integrated circuit of FIG. 1.

In the semiconductor integrated circuit shown in FIGS. 4 and 5, which has the shield layer 114, it is possible to prevent generation of coupling capacitance between the paired electrodes (nodes A and B) constituting the MOS capacitance and the paired electrodes (nodes C and D) constituting the inter-wire capacitance. It is also possible to prevent occurrence of crosstalk between the vertically coinciding MOS capacitance and inter-wire capacitance.

The shield layer may be formed, not in the first metal layer, but in another metal layer. In this case, also, coupling between electrodes formed above and below the shield layer can be prevented.

### Second Alteration

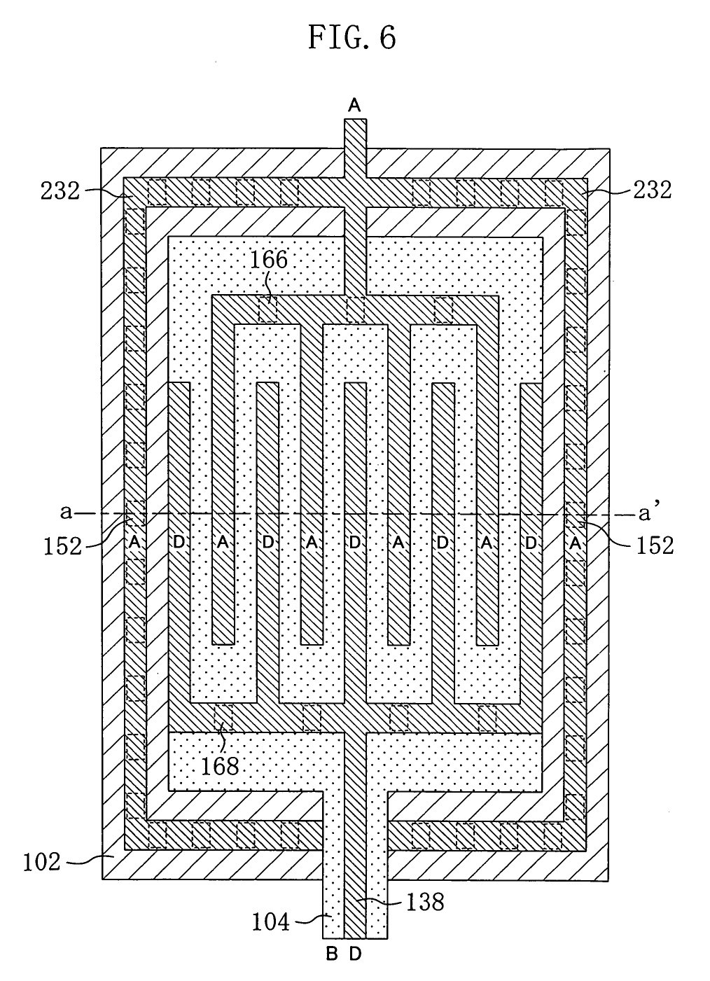

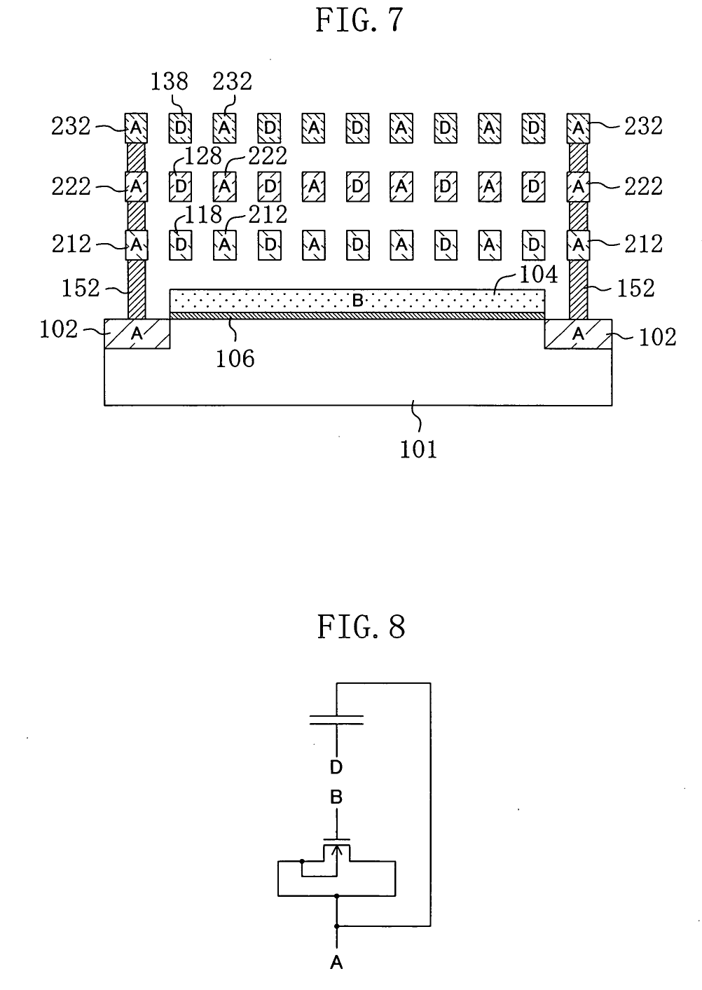

FIG. 6 is a layout diagram of a semiconductor integrated circuit of the second alteration to Embodiment 1. FIG. 7 is a cross-sectional view of the semiconductor integrated circuit of FIG. 6 taken along line a-a′. FIG. 8 is a circuit diagram showing a circuit equivalent to the semiconductor integrated circuit of FIG. 6.

The semiconductor integrated circuit of FIG. 6 is different from the semiconductor integrated circuit of FIG. 1 in that an interconnect 212 is provided, in place of the interconnects 112 and 113 and the comb electrode 116, by connecting these interconnects and electrode with one another via interconnects in the first metal layer. Likewise, an interconnect 222 is provided, in place of the interconnects 122 and 123 and the comb electrode 126, by connecting these interconnects and electrode with one another via interconnects in the second metal layer, and an interconnect 232 is provided, in place of the interconnects 132 and 133 and the comb electrode 136, by connecting these interconnects and electrode with one another via interconnects in the third metal layer. The other configuration of the semiconductor integrated circuit of FIG. 6 is substantially the same as that of the semiconductor integrated circuit of FIG. 1.

With the above configuration, capacitances can be formed between node A and node B and between node A and node D as shown in FIG. 8.

Note that it is good enough to connect the interconnects 112, 113, 122, 123, 132, 133 with the comb electrode 116, 126, 136 in at least one metal layer.

### Third Alteration

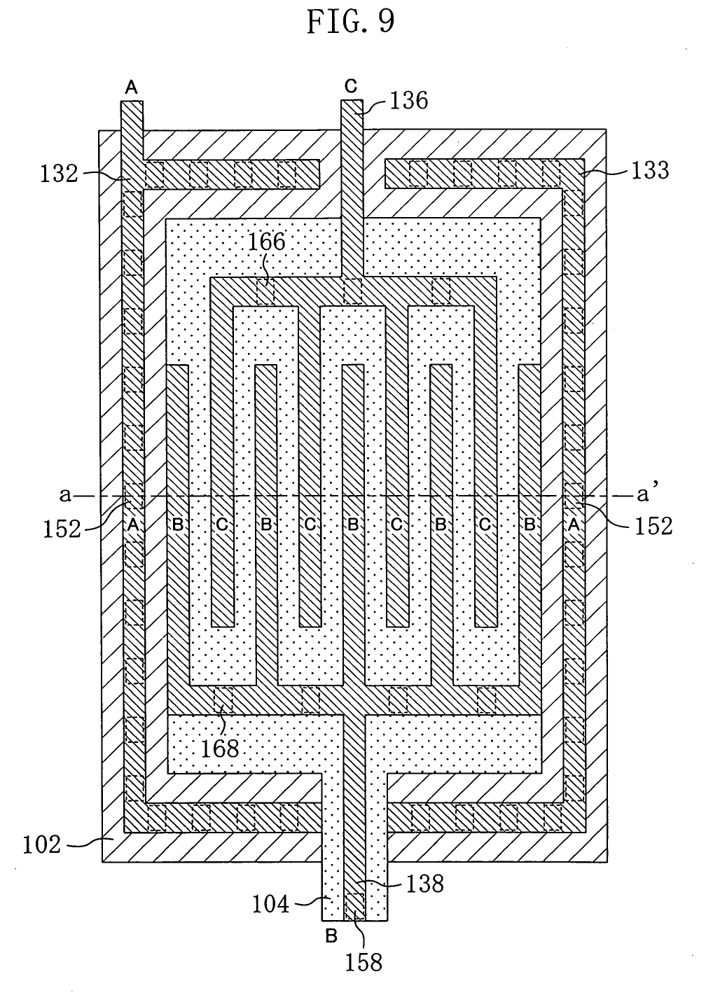

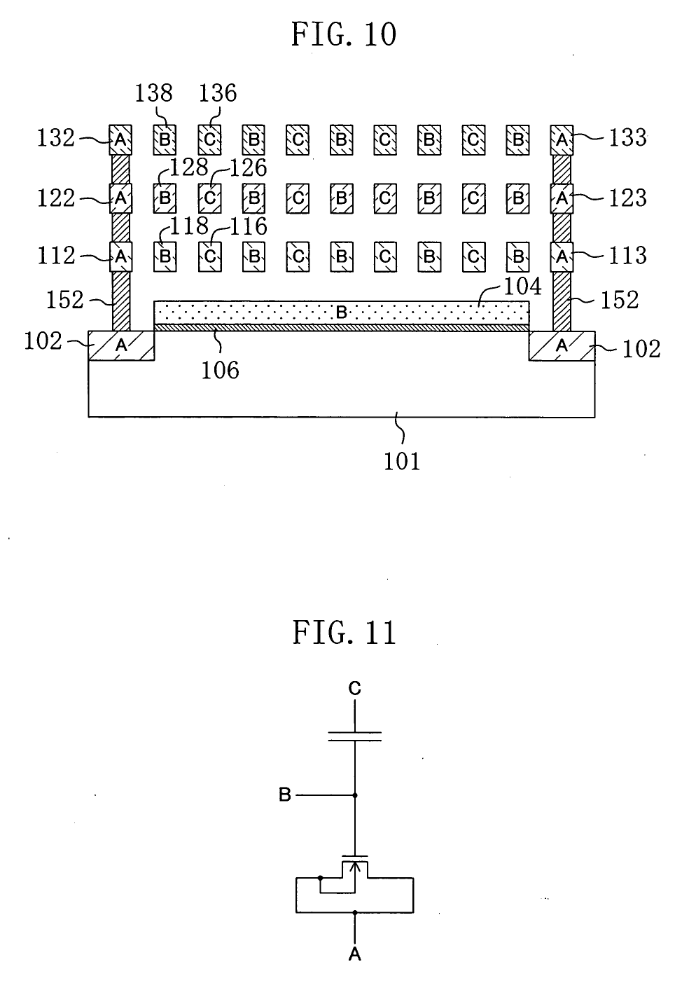

FIG. 9 is a layout diagram of a semiconductor integrated circuit of the third alteration to Embodiment 1. FIG. 10 is a cross-sectional view of the semiconductor integrated circuit of FIG. 9 taken along line a-a′. FIG. 11 is a circuit diagram showing a circuit equivalent to the semiconductor integrated circuit of FIG. 9.

The semiconductor integrated circuit of FIG. 9 is different from the semiconductor integrated circuit of FIG. 1 in that the polysilicon gate 104 is connected with the comb electrode 118 in the first metal layer via a contact 158. The other configuration of the semiconductor integrated circuit of FIG. 9 is substantially the same as that of the semiconductor integrated circuit of FIG. 1.

With the above configuration, capacitances can be formed between node B and node A and between node B and node C as shown in FIG. 11.

In the first metal layer, the spacing between the interconnect 112 and the teeth of the comb electrode 118 and the spacing between the interconnect 113 and the teeth of the comb electrode 118 may be the smallest possible pitch, to permit formation of larger capacitance. This also applies to the second and third metal layers.

### Fourth Alteration

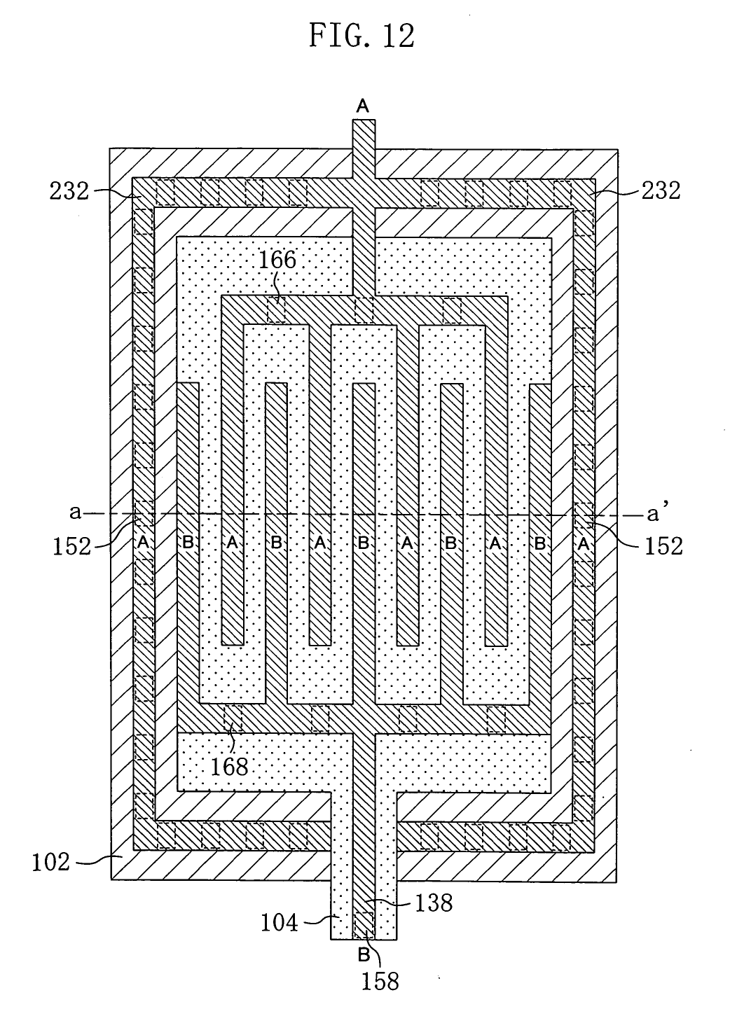

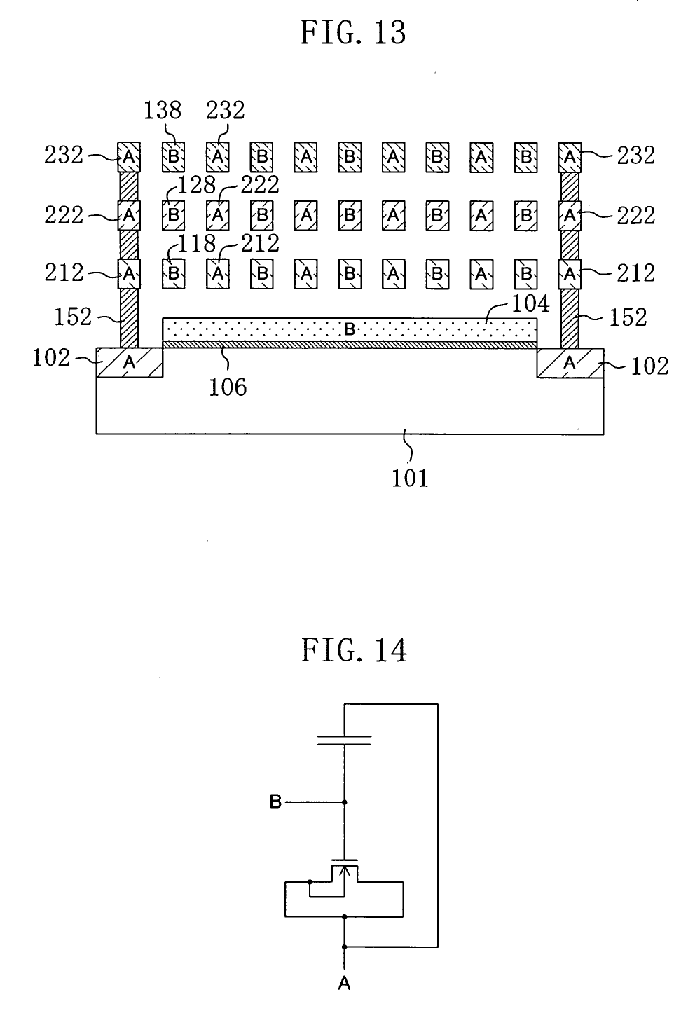

FIG. 12 is a layout diagram of a semiconductor integrated circuit of the fourth alteration to Embodiment 1. FIG. 13 is a cross-sectional view of the semiconductor integrated circuit of FIG. 12 taken along line a-a′. FIG. 14 is a circuit diagram showing a circuit equivalent to the semiconductor integrated circuit of FIG. 12.

The semiconductor integrated circuit of FIG. 12 is different from the semiconductor integrated circuit of FIG. 6 in that the polysilicon gate 104 is connected with the comb electrode 118 in the first metal layer via a contact 158. The other configuration of the semiconductor integrated circuit of FIG. 12 is substantially the same as that of the semiconductor integrated circuit of FIG. 6.

With the above configuration, the inter-wire capacitance and the MOS capacitance can be formed in parallel between node A and node B as shown in FIG. 14.

### Fifth Alteration

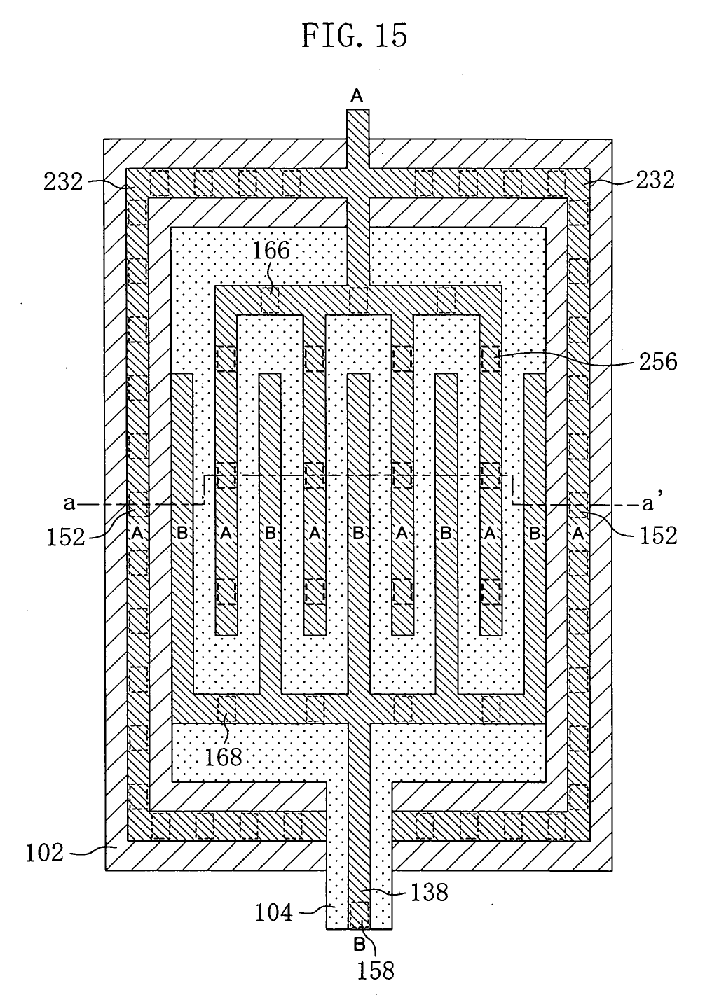

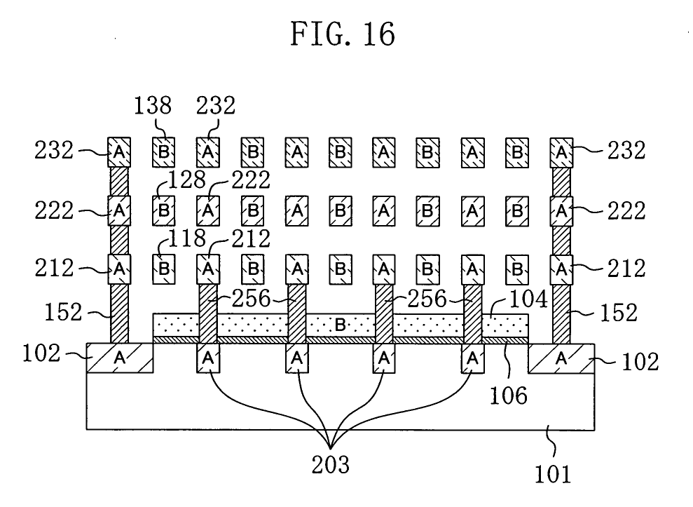

FIG. 15 is a layout diagram of a semiconductor integrated circuit of the fifth alteration to Embodiment 1. FIG. 16 is a cross-sectional view of the semiconductor integrated circuit of FIG. 15 taken along line a-a′.

The semiconductor integrated circuit of FIG. 15 is different from the semiconductor integrated circuit of FIG. 12 in that a plurality of diffusion regions 203 are formed in the semiconductor substrate 101 under the polysilicon gate 104 and a plurality of contacts 256 are formed under the teeth of the comb-shaped portion of the interconnect 212. The contacts 256 connect the interconnect 212 with their underlying diffusion regions 203. The polysilicon gate 104 and the gate oxide film 106 have holes to allow the contacts 256 to pass therethrough. The other configuration of the semiconductor integrated circuit of FIG. 15 is substantially the same as that of the semiconductor integrated circuit of FIG. 12.

With the above configuration, the potential of the semiconductor substrate 101 can be fixed to the potential of the interconnect 212 in the first metal layer and the diffusion region 102 (node A) irrespective of the area of the polysilicon 104. In particular, when the area of the polysilicon gate 104 is large, the potential of the underlying semiconductor substrate 101 can be kept from becoming nonuniform.

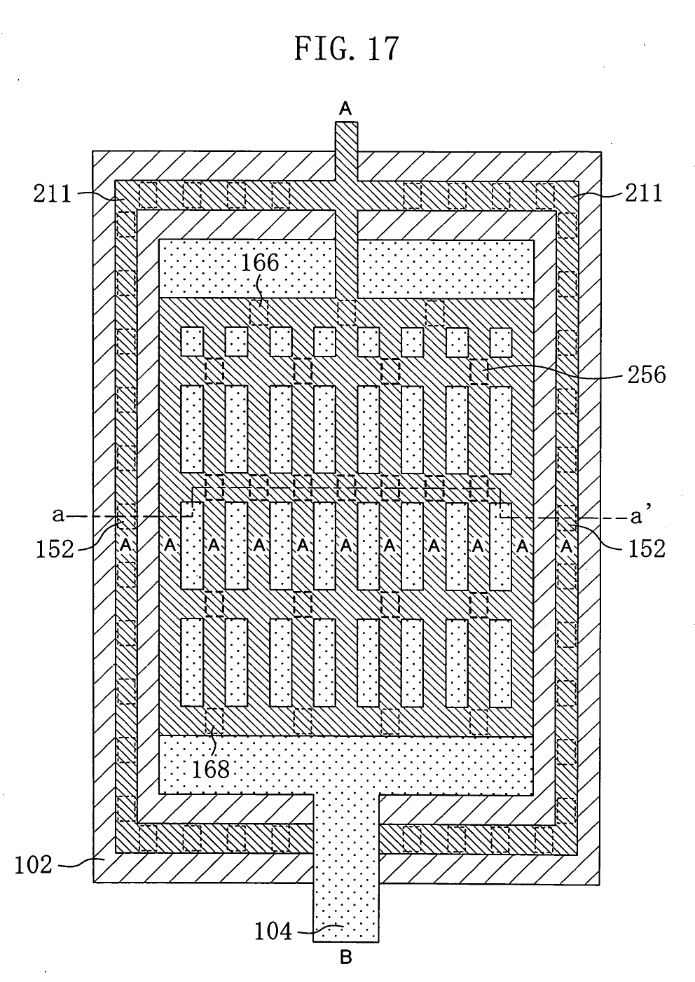

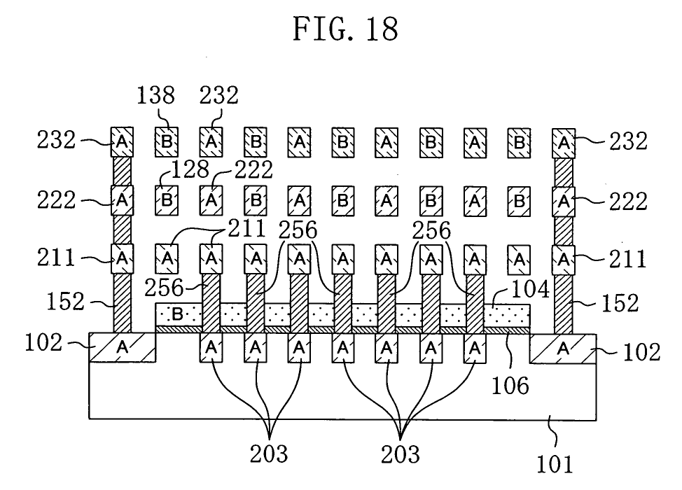

An electrode in a shape other than the comb shape may be formed in the first metal layer. An example of such an electrode will be described. FIG. 17 is a layout diagram of an alteration to the semiconductor integrated circuit of FIG. 15. FIG. 18 is a cross-sectional view of the semiconductor integrated circuit of FIG. 17 take along line a-a′. Note that FIG. 17 shows only the first metal layer and its underlying layers.

The semiconductor integrated circuit of FIG. 17 is different from the semiconductor integrated circuit shown in FIGS. 15 and 16 in that an interconnect (electrode) 211 is provided in place of the interconnect 212 and the comb electrode 118 and also further more diffusion regions 203 are formed in the semiconductor substrate 101. The interconnect 211 is different from the interconnect 212 in having no comb-shaped portion and instead having a lattice-shaped portion formed above the polysilicon gate 104. A plurality of contacts 256 are formed under the lattice-shaped portion of the interconnect 211, and a plurality of diffusion regions 203 are formed in the semiconductor substrate 101 under the contacts 256. The contacts 256 connect the lattice-shaped portion of the interconnect 211 with their underlying diffusion regions.

In the semiconductor integrated circuit of FIG. 17, in which a larger number of contacts can be provided, the potential of the semiconductor substrate 101 underlying the polysilicon gate 104 can be made more uniform.

### Sixth Alteration

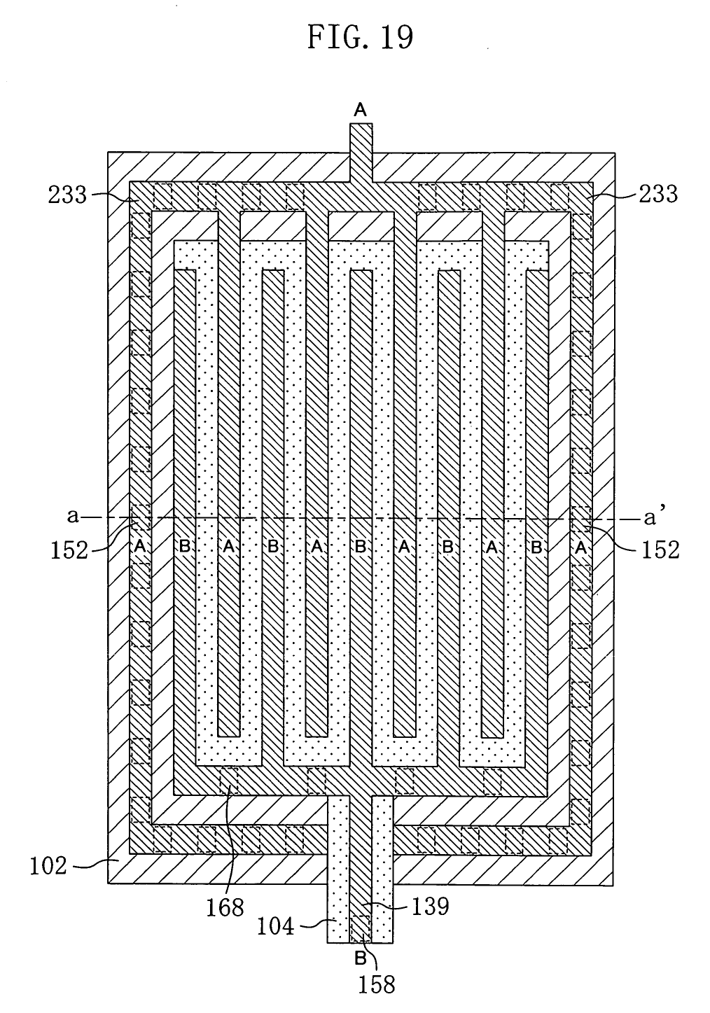

FIG. 19 is a layout diagram of a semiconductor integrated circuit of the sixth alteration to Embodiment 1.

The semiconductor integrated circuit of FIG. 19 is different from the semiconductor integrated circuit of FIG. 12 in that an interconnect 233 and a comb electrode 139, in place of the interconnect 232 and the comb electrode 138, are formed in the third metal layer. The other configuration of the semiconductor integrated circuit of FIG. 19 is substantially the same as that of the semiconductor integrated circuit of FIG. 12. The interconnect 233 has its teeth directly branching from the portions thereof corresponding to the interconnects 132 and 133 in the semiconductor integrated circuit of FIG. 1, and the teeth are elongated upward and downward as viewed from FIG. 19 compared with the teeth of the comb-shaped portion of the interconnect 232. The interconnect 139 has its teeth elongated upward and downward as viewed from FIG. 19 compared with the teeth of the comb-shaped portion of the interconnect 138. The first and second metal layers are also configured as described above. This configuration permits increase in inter-wire capacitance without changing the circuit area.

Note that it is good enough to configure the interconnect and the comb electrode as shown in FIG. 19 in at least one metal layer.

### Embodiment 2

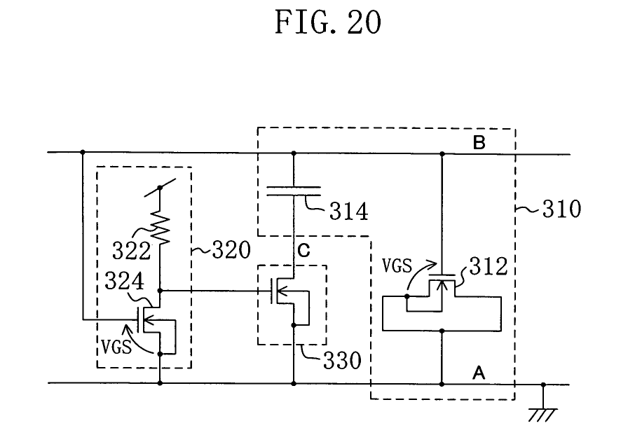

FIG. 20 is a circuit diagram of a semiconductor integrated circuit of Embodiment 2. The semiconductor integrated circuit of FIG. 20 includes a capacitance circuit 310, a switch control circuit 320 and a switch circuit 330. The capacitance circuit 310 includes an NMOS transistor 312 and an inter-wire capacitance 314. The NMOS transistor 312 is used as a MOS capacitance between node A and node B. The inter-wire capacitance 314 exists between node B and node C.

The capacitance circuit 310 is the semiconductor integrated circuit of FIG. 9, for example. The switch control circuit 320 includes a resistance 322 and an NMOS transistor 324. A high voltage such as the power supply voltage is applied to one terminal of the resistance 322, and the other terminal of the resistance 322 is connected to the drain of the NMOS transistor 324. The source and gate of the NMOS transistor 324 are respectively connected to node A and node B. Node A is grounded. The switch circuit 330 is composed of an NMOS transistor whose source, drain and gate are respectively connected to node A, node C and the drain of the MOS transistor 324. Assume that the NMOS transistor 312 and the NMOS transistor 324 have roughly the same threshold voltage VT.

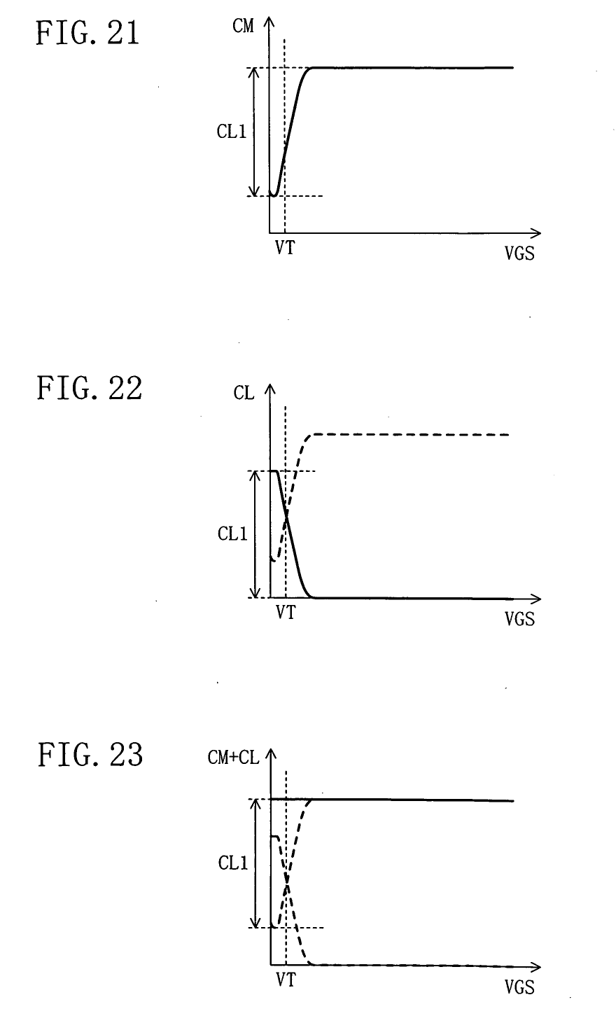

FIG. 21 is a graph showing the C-V characteristic of the MOS transistor 312 in FIG. 20. The C-V characteristic refers to the characteristic representing the relationship between the source-gate voltage and the capacitance value CM of the MOS capacitance in the NMOS transistor 312.

In the NMOS transistor 312, as the source-gate voltage VGS increases, a depletion layer emerges under the gate oxide film. The MOS capacitance is therefore a capacitance obtained by serially connecting the capacitance of the depletion layer and the capacitance of the gate oxide film. Once the voltage VGS exceeds the threshold voltage VT of the MOS transistor 312, a channel is formed under the gate oxide film, turning ON the NMOS transistor 312. The MOS capacitance at this time is equal to only the capacitance of the gate oxide film. As a result, the C-V characteristic is as shown in FIG. 21.

As described above, the value of the MOS capacitance varies with the voltage VGS. For this reason, the MOS capacitance is generally inappropriate as the capacitance used for analog circuits requiring high precision, such as AD converters, DA converters and low-pass filters.

FIG. 22 is a graph showing a capacitance CL between node B and node A by the inter-wire capacitance 314 in FIG. 20. The voltage VGS is equal to the voltage at node B. To compensate a capacitance variation CL1 at and around the threshold voltage VT of the NMOS transistor 312, the inter-wire capacitance 314 is designed to have the capacitance CL1.

When node B is fixed to the ground voltage GND, the NMOS transistor 324 of the switch control circuit 320 is OFF. The NMOS transistor of the switch circuit 330 is then ON because a high voltage is being applied to the gate of this NMOS transistor via the resistance 322. In this state, the capacitance CL between node B and node A by the inter-wire capacitance 314 is equal to the capacitance CL1.

If a voltage equal to or higher than the threshold voltage VT is applied to node B, the NMOS transistor 324 goes ON, which turns OFF the NMOS transistor of the switch circuit 330 whose gate potential lowers. In this state, the inter-wire capacitance 314 is no more influential on the capacitance between node B and node A.

FIG. 23 is a graph showing a capacitance CM+CL between node B and node A of the semiconductor integrated circuit of FIG. 20. FIG. 23 is obtained by summing the value in FIG. 21 and the value in FIG. 22. Thus, in the semiconductor integrated circuit of FIG. 20, the inter-node capacitance can be kept fixed irrespective of a variation in node voltage. The semiconductor integrated circuit of FIG. 20, therefore, permits use of a semiconductor integrated circuit having a MOS capacitance as described in Embodiment 1 for a high-precision analog circuit. Since the MOS capacitance is large in capacitance value per unit, the circuit area of the semiconductor integrated circuit can be reduced.

Although the above description was made assuming that the capacitance circuit 310 was the semiconductor integrated circuit of FIG. 9, the comb electrodes 116, 118, 126, 128, 136 and 138 may be formed not to overlap the polysilicon gate 104 or the diffusion region 102. Also, in place of the resistance 322, a transistor, for example, may be used as a resistance.

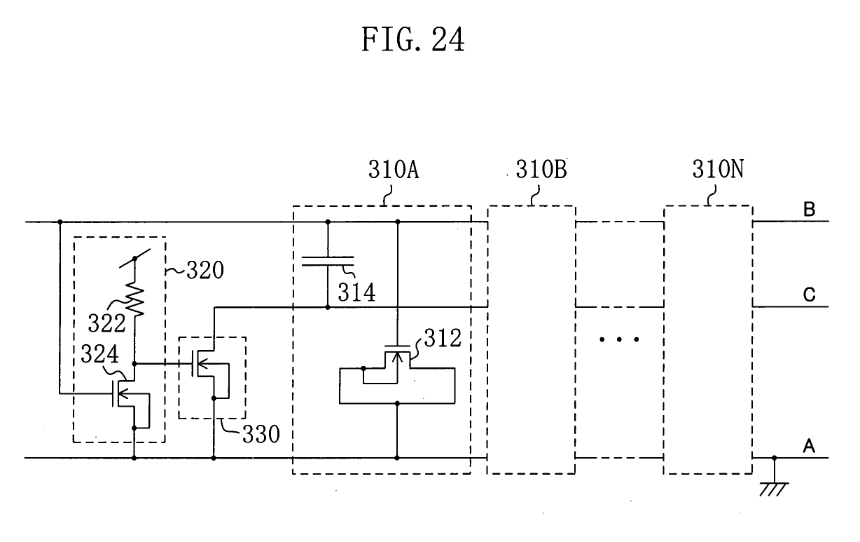

FIG. 24 is a circuit diagram showing an example of configuration of a semiconductor integrated circuit having a larger capacitance. The semiconductor integrated circuit of FIG. 24 includes capacitance circuits 310A, 310B, . . . , 310N, a switch control circuit 320 and a switch circuit 330. The capacitance circuits 310A to 310N respectively have substantially the same configuration as the capacitance circuit 310 in FIG. 20. The switch control circuit 320 and the switch circuit 330 are substantially the same as those in FIG. 20.

The semiconductor integrated circuit of FIG. 24 has a large capacitance and also can keep the inter-node capacitance fixed irrespective of a variation in node voltage.

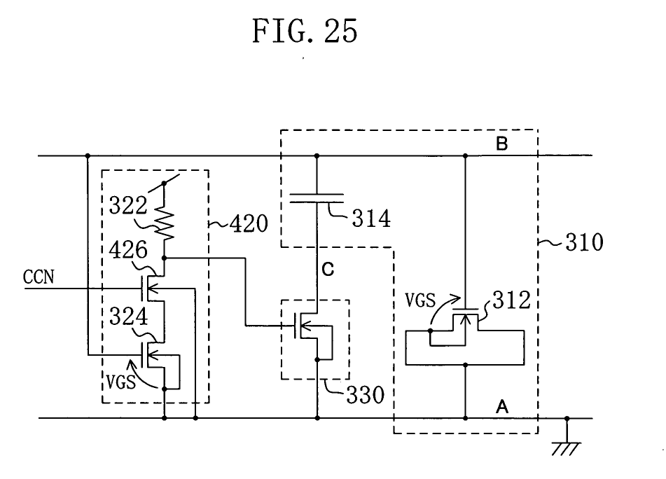

FIG. 25 is a circuit diagram showing an alteration to the semiconductor integrated circuit of FIG. 20. The semiconductor integrated circuit of FIG. 25 is different from the semiconductor integrated circuit of FIG. 20 in that a switch control circuit 420 is provided in place of the switch control circuit 320. The switch control circuit 420 is different from the switch control circuit 320 in that an NMOS transistor 426 is placed between the resistance 322 and the NMOS transistor 324. A control signal CCN is applied to the gate of the NMOS transistor 426.

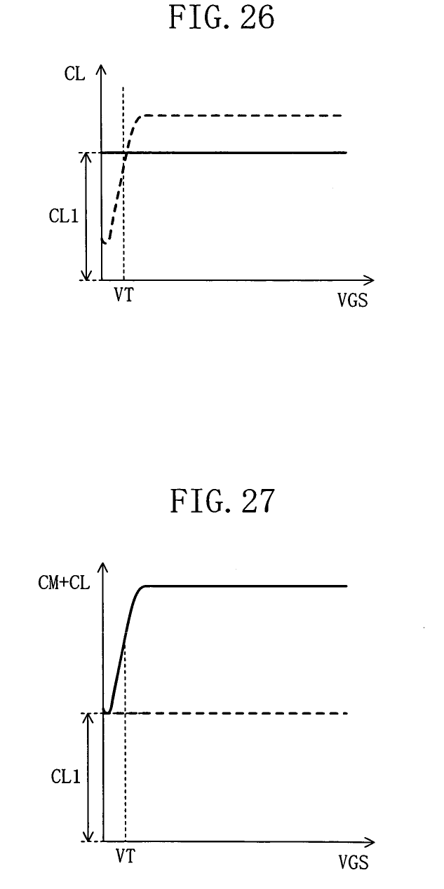

FIG. 26 is a graph showing a capacitance CL between node B and node A by the inter-wire capacitance 314 obtained when the control signal CCN is at a low potential. FIG. 27 is a graph showing a capacitance CM+CL between node B and node A obtained when the control signal CCN is at a low potential.

When the control signal CCN is at a high potential, the NMOS transistor 426 is ON. The semiconductor integrated circuit of FIG. 25 therefore operates in substantially the same manner as the semiconductor integrated circuit of FIG. 20. When the control signal CCN is at a low potential, the NMOS transistor 426 is OFF, allowing the NMOS transistor of the switch circuit 330 to keep being ON. Therefore, the capacitance CL between node B and node A by the inter-wire capacitance 314 is equal to the capacitance CL1 irrespective of the voltage at node B.

Hence, in the semiconductor integrated circuit of FIG. 25, it is possible to select either keeping the inter-node capacitance fixed irrespective of a variation in node voltage or maximizing the inter-node capacitance.

As described above, the present invention permits increase in the capacitance per unit area, and thus is useful in a semiconductor integrated circuit having an analog circuit and the like.

What is claimed is:

1. A semiconductor integrated device comprising:
a first electrode;
a transistor, having a second electrode, formed on a semiconductor substrate; and
third and fourth electrodes formed in a same metal layer,
wherein the first electrode is connected with a diffusion region constituting the transistor,
the second electrode constitutes a gate of the transistor,
the third and fourth electrodes are respectively in a comb shape and formed to at least partly overlie the transistor, and
none of the first to fourth electrodes is connected with any of the other electrodes.

2. The semiconductor integrated circuit of claim 1, wherein both the third and fourth electrodes are formed in a plurality of metal layers,
the third electrodes in the plurality of metal layers are connected mutually, and
the fourth electrodes in the plurality of metal layers are connected mutually.

3. The semiconductor integrated circuit of claim 1, wherein a shield layer is formed between the second electrode and the third electrode.

4. A semiconductor integrated device comprising:
a first electrode;
a transistor, having a second electrode, formed on a semiconductor substrate; and
third and fourth electrodes formed in a same metal layer,
wherein the first electrode is connected with a diffusion region constituting the transistor,
the second electrode constitutes a gate of the transistor,
the third and fourth electrodes are respectively in a comb shape and formed to at least partly overlie the transistor, and
the first electrode and the third electrode are connected with each other.

5. The semiconductor integrated circuit of claim 4, further comprising:
a diffusion region formed in the semiconductor substrate under the second electrode; and
a contact for connecting the third electrode with the diffusion region formed in the semiconductor substrate.

6. The semiconductor integrated circuit of claim 4, further comprising:
a diffusion region formed in the semiconductor substrate under the second electrode;
an electrode in a lattice shape formed between the second electrode and the third electrode; and
a contact for connecting the lattice-shaped electrode with the diffusion region formed in the semiconductor substrate.

7. The semiconductor integrated circuit of claim 4, wherein comb teeth of the third electrode branch directly from the first electrode.

8. A semiconductor integrated device comprising:
a first electrode;
a transistor, having a second electrode, formed on a semiconductor substrate; and
third and fourth electrodes formed in a same metal layer,
wherein the first electrode is connected with a diffusion region constituting the transistor,
the second electrode constitutes a gate of the transistor,
the third and fourth electrodes are respectively in a comb shape and formed to at least partly overlie the transistor, and
the second electrode and the fourth electrode are connected with each other.

9. The semiconductor integrated circuit of claim 8, wherein the fourth electrode has a portion roughly parallel to the first electrode.

10. The semiconductor integrated circuit of claim 9, wherein the spacing between the portion of the fourth electrode roughly parallel to the first electrode and the first electrode is roughly equal to the spacing between the portion of the fourth electrode roughly parallel to the first electrode and the third electrode.

11. A semiconductor integrated circuit comprising:
a capacitance circuit connected to first to third nodes;
a switch circuit connected between the first node and the third node; and
a switch control circuit for controlling the switch circuit so as to be ON when the voltage between the first and second nodes is low,
wherein the capacitance circuit comprises:
a transistor having a source and a drain connected to the first node and a gate 25 connected to the second node; and
two comb-shaped electrodes formed in a same metal layer and respectively connected to the second and third nodes.

12. The semiconductor integrated circuit of claim 11, wherein the switch control circuit comprises:
a resistance element having one terminal receiving a high potential; and
a transistor having a source connected to the first node, a gate connected to the second node and a drain connected to the other terminal of the resistance element, and
the switch circuit comprises:
a transistor having a source connected to the first node, a gate connected to the drain of the transistor of the switch control circuit and a drain connected to the third node.

13. The semiconductor integrated circuit of claim 12, wherein the switch control circuit further comprises:
a transistor connected in series between the other terminal of the resistance element and the drain of the transistor of the switch control circuit.

14. The semiconductor integrated circuit of claim 11, further comprising:
an additional capacitance circuit same as the capacitance circuit.

15. The semiconductor integrated circuit of claim 11, wherein the two comb-shaped electrodes are respectively formed to at least partly overlie the transistor.
